(19) United States
(12) Patent Application Publication
(10) Pub. No.: US 2021/0028056 A1
(43) Pub. Date: Jan. 28, 2021

(54) ELECTRONIC CIRCUIT COMPRISING ELECTRICAL INSULATION TRENCHES

(71) Applicants: Commissariat à I'Énergie Atomique et aux Énergies Alternatives, Paris (FR); Aledia, Grenoble (FR)

(72) Inventors: Adrien Gasse, Seyssins (FR); Vincent Beix, Fontaine (FR); Sylvie Jaryayes, Sassenage (FR); Brigitte Soulier, Grenoble (FR); Marion Volpert, Sassenage (FR)

(73) Assignees: Commissariat à I'Énergie Atomique et aux Énergies Alternatives, Paris (FR); Aledia, Grenoble (FR)

(21) Appl. No.: 16/645,065

(22) PCT Filed: Sep. 12, 2018
(86) PCT No.: PCT/FR2018/052239

§ 371 Date: Mar. 6, 2020

(30) Foreign Application Priority Data
Sep. 19, 2017 (FR) 1758664

(51) Int. Cl. H01L 21/762; H01L 21/02; H01L 23/14

(52) U.S. Cl. CPC H01L 21/76232; H01L 21/02532; H01L 23/147; H01L 21/76281; H01L 21/76237

(57) ABSTRACT

An electronic circuit including a semiconductor substrate having first and second opposite surfaces and electric insulation trenches. Each trench separates first and second portions of the substrate and includes electrically-insulating walls made of a first electrically-insulating material, extending from the first surface to the second surface, and a core made of a filling material, separated from the substrate by the walls. For at least one of the trenches, the trench walls include electrically-insulating portions made of the first electrically-insulating material protruding from the first or second surface outside of the substrate and/or the trench includes an electrically-insulating wall made of the first electrical-insulating material protruding from the first or second surface outside of the substrate and coupling the trench walls.

The present patent application claims the priority benefit of French patent application FR17/58664 which is herein incorporated by reference.

### BACKGROUND

The present application concerns an electronic circuit comprising electric insulation trenches.

### DISCUSSION OF THE RELATED ART

Generally, an electronic circuit comprises a semiconductor substrate having electronic components formed inside and on top of it. For certain applications, it is desirable to electrically insulate different portions of the semiconductor substrate from one another. This can be obtained by forming in the substrate electrically-insulating trenches which extend across the entire thickness of the substrate and which divide the substrate into portions electrically insulated from one another.

FIGS. 1 and 2 are cross-section views of an example of an electronic circuit 5. FIG. 1 is a cross-section view of FIG. 2 along line I-I and FIG. 2 is a cross-section view of FIG. 1 along line II-II. Electronic circuit 5 comprises a semiconductor substrate 6 having a front surface 8 and a rear surface 10, opposite to front surface 8, and further comprises, in substrate 6, criss-cross electric insulation trenches 12, 14 which delimit portions 16 of substrate 6. Electronic components 17, schematically shown in FIGS. 1 and 2 by rectangles, are formed in portions 16 and/or on portions 16. These are for example metal-oxide gate field effect transistors (MOS transistors), diodes, light-emitting diodes, and/or photodiodes.

Trenches 12 extend, in the cross-section view of FIG. 1, along a first direction and trenches 14 extend in top view along a second direction inclined with respect to the first direction, for example perpendicular to the first direction. Trenches 12, 14 have substantially the shape of strips in top view. Trenches 12, 14 extend in substrate 6 from surface 8 across the entire thickness of substrate 6.

As an example, each trench 12, 14 comprises two substantially planar opposite lateral sides 18A, 18B, for example, substantially parallel, covered with an electrically-insulating wall 19A, 19B of thickness Eₒₓ, core 20 of trench 12, 14 being filled with a filling material, for example, a semiconductor material. Insulating wall 19A, 19B may have a substantially constant thickness. As a variation, the thickness of insulating wall 19A, 19B may be non-constant. In this case, thickness Eₒₓ corresponds to the minimum thickness of insulating wall 19A, 19B. Call lateral dimension L of each trench 12, 14 the distance between the two lateral sides 18A, 18B. As a variation, lateral sides 18A, 18B may be substantially inclined with respect to each other, lateral sides 18A, 18B for example coming closer to each other, with an increasing distance from surface 8. In this case, the lateral dimension L of trench 12, 14 corresponds to the average distance separating the two lateral sides 18A, 18B.

Electronic circuit 5 further comprises an electrically-insulating layer 22 or a stack of electrically-insulating layers on surface 8 and an electrically-insulating layer 24 or a stack of electrically-insulating layers on surface 10. Contact pads, not shown, may be provided on the side of surface 10, through insulating layer 24 in contact with portions 16 of the substrate.

Thickness Eₒₓ and lateral dimension L are generally determined by simulation according to the voltage behavior desired for trench 12, 14, that is, the minimum voltage, called breakdown voltage, applied between two adjacent portions 16 of substrate 6 for which trench 12, 14 becomes electrically conductive. Dimensions L and Eₒₓ are generally determined by simulation. According to the targeted applications, trenches 12, 14 should withstand voltages which may be greater than 100 V, or even than several hundred volts, for example, 500 V.

However, in certain cases, the breakdown voltage really measured may be smaller than the breakdown voltage provided by simulation.

### SUMMARY

An object of an embodiment is to provide an electronic circuit comprising electric insulation trenches overcoming all or part of the disadvantages of the previously-described trenches.

Another object of an embodiment is to increase the breakdown voltage of electric insulation trenches.

Another object of an embodiment is for the method of manufacturing electric insulation trenches to comprise a small number of additional steps as compared with a method of manufacturing conventional electric insulation trenches.

Thus, an embodiment provides an electronic circuit comprising a semiconductor substrate having first and second opposite surfaces and electric insulation trenches extending in the substrate from the first surface to the second surface, each trench separating first and second portions of the substrate and comprising electrically-insulating walls made of a first electrically-insulating material, extending from the first surface to the second surface, and a core made of a filling material, separated from the substrate by the walls. For at least one of the trenches, the trench walls comprise electrically-insulating portions made of the first electrically-insulating material protruding from the first or second surface outside of the substrate and/or the trench comprises an electrically-insulating side made of the first electrically-insulating material protruding from the first or second surface outside of the substrate and coupling the trench walls.

According to an embodiment, the electronic circuit further comprises an electrically-insulating layer of a second electrically-insulating material covering the electrically-insulating portions or the electrically-insulating side.

According to an embodiment, the breakdown voltage of the first electrically-insulating material is greater than the breakdown voltage of the second electrically-insulating material.

According to an embodiment, the height of the electrically-insulating portions or of the electrically-insulating side protruding from the first or second surface is in the range from 0.05 μm to 5 μm.

According to an embodiment, for at least one of the trenches, the junction between the first or second surface and each wall of the trench comprises an edge rounded towards the inside of the substrate.

According to an embodiment, the radius of curvature of each rounded edge, in a plane perpendicular to the walls of the trench, is greater than 0.05 μm.

According to an embodiment, the first electrically-insulating material is made of silicon oxide, of silicon nitride, of silicon oxynitride, or hafnium oxide, or of diamond.

According to an embodiment, the walls are made of thermal silicon oxide.

According to an embodiment, the filling material is different from the first electrically-insulating material.

According to an embodiment, the filling material is selected from the group comprising silicon, germanium, silicon carbide, III-V compounds, or II-VI compounds.

According to an embodiment, the substrate is made of silicon, of germanium, of silicon carbide, of a III-V compound, or of a II-VI compound.

According to an embodiment, the electronic circuit comprises at least first and second electronic components, the first electronic component resting on a first portion of the substrate and the second electronic component resting on a second portion of the substrate, one of the electric insulation trenches separating the first portion from the second portion.

An embodiment also provides a method of manufacturing the electronic circuit such as previously defined, comprising the successive steps of:

a) forming openings in the substrate from the first surface across a portion of the substrate thickness;

b) forming an electrically-insulating layer of the first electrically-insulating material at least in each opening;

c) depositing a layer of the filling material in each opening in contact with the first electrically-insulating layer; and

d) thinning the substrate from the second surface to bring the second surface closer to the first surface to reach at least the electrically-insulating layer and form, for at least one of the trenches, the electrically-insulating portions of the first electrically-insulating material protruding from the second surface outside of the substrate and/or the electrically-insulating side of the first electrically-insulating material protruding from the second surface outside of the substrate and coupling the trench walls.

According to an embodiment, step b) comprises a thermal oxidation step.

According to an embodiment, the method further comprises the steps of:

e) forming, for at least one of the trenches, a groove in the substrate along each wall of the trench, on the side of the first or second surface; and

f) etching the substrate across a portion of its thickness, whereby the junction between the first or second surface and each wall of the trench comprises an edge rounded towards the inside of the substrate.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIGS. 1 and 2, previously described, are partial simplified cross-section views of an example of an electronic circuit comprising electric insulation trenches;

FIG. 3 is a partial simplified cross-section view of an electronic circuit comprising an electric insulation trench according to an embodiment;

FIGS. 4A to 4J are partial simplified cross-section views of structures obtained at successive steps of an embodiment of a method of manufacturing the electric insulation trench of the electronic circuit of FIG. 3;

FIG. 5 is a partial simplified cross-section view of an electronic circuit comprising an electric insulation trench according to another embodiment;

FIGS. 6A to 6C are partial simplified cross-section views of structures obtained at successive steps of an embodiment of a method of manufacturing the electric insulation trench of the electronic circuit of FIG. 5;

FIG. 7 is a partial simplified cross-section view of an electronic circuit comprising an electric insulation trench according to another embodiment;

FIGS. 8A to 8G are partial simplified cross-section views of structures obtained at successive steps of an embodiment of a method of manufacturing the electric insulation trench of an electronic circuit similar to the electronic circuit of FIG. 7; and

FIGS. 9A to 9D are partial simplified cross-section views of structures obtained at successive steps of another embodiment of another method of manufacturing the electric insulation trench of an electronic circuit similar to the electronic circuit of FIG. 7.

### DETAILED DESCRIPTION

The same elements have been designated with the same reference numerals in the various drawings and, further, the various drawings are not to scale. In the following description, when reference is made to terms qualifying the relative position, such as term “top”, “upper”, or “lower”, etc., reference is made to the orientation of the drawings or to an electronic device in a normal position of use. For clarity, only those steps and elements which are useful to the understanding of the described embodiments have been shown and are detailed. In particular, the electronic components of an electronic circuit are well known in the art and are not described in detail hereafter. Unless otherwise specified, expressions “approximately”, “substantially”, “around”, and “in the order of” mean to within 10% and, preferably, to within 5%. In the following description, a material having a resistivity greater than 10³ am is called “electrically-insulating material” and a material having an electric resistivity in the range from 0.1 am and 10³ am is called “semiconductor material”. In the following description, an element having its longitudinal direction, measured in a plane parallel to the surfaces of the substrate, greater than at least five times, preferably than at least ten times, the lateral dimension of the trench measured in this plane, is called electric insulation trench of a substrate.

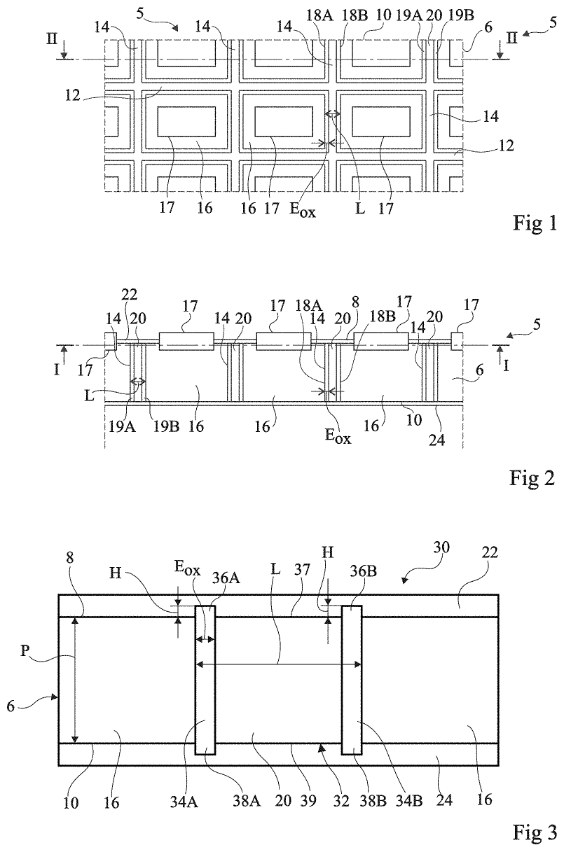

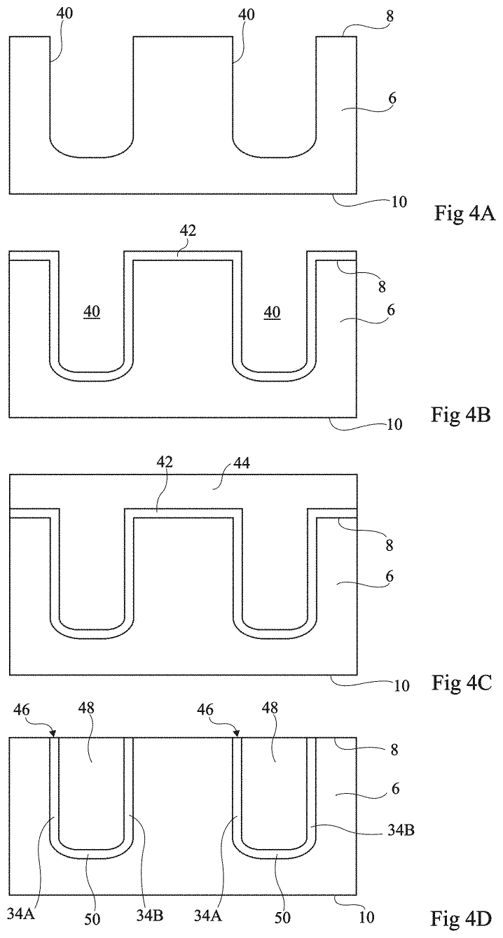

The inventors have shown that, for the electric insulation trench structure 12, 14 shown in FIGS. 1 and 2, an electric arc tends to form in preferred fashion in case of a breakdown between portion 16 and core 20 through insulating layer 22 or 24 at the ends of insulating wall 19A, 19B. An explanation would be that insulating layer 22, 24 is generally made of an electrically-insulating material having poorer electronic properties than the electrically-insulating material forming insulating walls 19A, 19B, particularly due to the method of manufacturing these insulating layers. Another explanation would be that the geometry of the device causes point effects (electrostatic field having an amplitude locally higher than elsewhere) which favor the forming of electric arcs in case of a breakdown between portion 16 and core 20 through insulating layer 22 or 24 at the ends of insulating wall 19A, 19B.

An embodiment provides increasing the electric insulation at the top of the electric insulation trench to avoid the forming of an electric arc in this area. This enables to increase the breakdown voltage of the electric insulation trench and thus the maximum voltage of the electronic circuit.

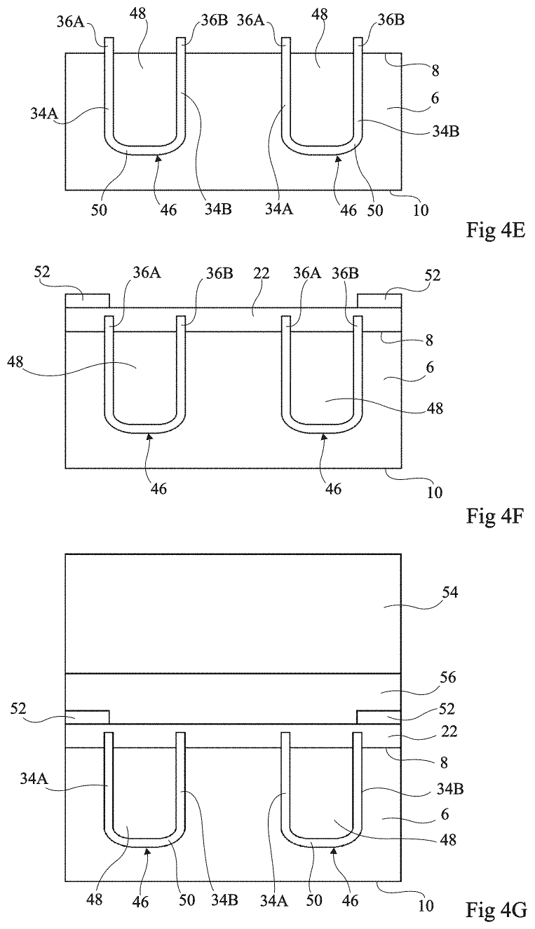

FIG. 3 shows an embodiment of an electronic circuit 30 comprising an electric insulation trench 32. Trench 32 comprises all the elements of the trench 12 or 14 shown in FIG. 1 or 2, with the difference that insulating walls 19A, 19B are replaced with insulating walls 34A, 34B having a thickness Eₒₓ, each insulating wall 34A, 34B comprising an end portion 36A, 36B which projects into insulating layer 22 and an end portion 38A, 38B which projects into insulating layer 24. According to an embodiment, end portions 36A, 36B, 38A, 38B are aligned with the rest of wall 34A, 34B. In the present embodiment, each end portion 36A, 36B protrudes from the front surface 8 of substrate 6 and from the front surface 37 of core 20. As a variation, each end portion 36A, 36B may not protrude from the front surface 37 of core 20. In the present embodiment, each end portion 38A, 38B protrudes from the rear surface 10 of substrate 6 and from the rear surface 39 of core 20. As a variation, it is possible for each end portion 38A, 38B not to protrude from the rear surface 39 of core 20. In FIG. 3, insulating layer 24 covers the entire surface 10. As a variation, a plurality of insulating layers 24 may be provided on surface 10, each layer 24 covering one of trenches 32.

The protruding height H of each end portion 36A, 36B, 38A, 38B in insulating layer 22 or 24 with respect to front or rear surface 8, 10 is in the range from 0.05 μm to 5 μm, for example, approximately 1 μm. In the embodiment shown in FIG. 3, the thickness of insulating layer 22 or 24 measured along the stacking direction of the layers on surface 8 or 10 is greater than height H. As a variation, the thickness of insulating layer 22 or 24 may be substantially equal to or smaller than height H.

In the embodiment shown in FIG. 3, insulating walls 34A, 34B of trench 32 protrude from substrate 6 on the side of front surface 8 and on the side of rear surface 10. According to the targeted applications, insulating walls 34A and 34B may protrude from substrate 6 only on the side of front surface 8 or only on the side of rear surface 10.

Substrate 6 may correspond to a monoblock structure or may correspond to a layer covering a support made of another material. Substrate 6 is preferably a semiconductor substrate, for example, a substrate made of silicon, of germanium, of silicon carbide, of a III-V compound, such as GaN or GaAs, or a ZnO substrate. Preferably, substrate 6 is a single-crystal silicon substrate. Preferably, it is a semiconductor substrate compatible with the manufacturing methods implemented in microelectronics. Substrate 6 may correspond to a multilayer structure of semiconductor-on-insulator type, also called SOI. As a variation, substrate 6 may correspond to a BSOI (Bonded Semiconductor On Insulator) structure. As a variation, substrate 6 may correspond to a stack of a plurality of silicon layers having different dopant concentrations, for example, of type P. The thickness P of the substrate 6 of electronic circuit 30, that is, the distance between surfaces 8, 10, obtained at the end of the method of manufacturing electronic circuit 30 which, as described in further detail hereafter, comprises a thinning step, may be in the range from 2 μm to 150 μm. Substrate 6 may be heavily doped, lightly-doped, or non-doped.

Each insulating layer 22, 24, which may have a monolayer or multilayer structure, may be made of a dielectric material, for example, of an inorganic dielectric material or of an organic dielectric material. Each insulating layer 22, 24 may be made of silicon oxide (SiO₂), of silicon nitride (SiₓN_{y}, where x is approximately equal to 3 and y is approximately equal to 4, for example, Si₃N₄), of silicon oxynitride (particularly of general formula SiOₓN_{y}, for example, Si₂ON₂), of hafnium oxide (HfO₂), or of diamond, or of SiNR, where R is an organic group, such as polyimide, epoxies, polyurethane, polynorbornenes, benzocyclobutene, polytetrafluoroethylene (PTFE), polyarylene, ethers, parylene, hydrogen silsesquioxane (HSQ), methyl silsesquioxane (MSQ). As an example, the thickness of each insulating layer 22, 24 is in the range from 25 nm to 5 μm, for example, equal to approximately 150 nm. Each insulating layer 22, 24 may be formed by a deposition method, particularly a chemical vapor deposition (CVD) method, particularly a plasma-enhanced chemical vapor deposition (PECVD) method, for example, at temperatures in the range from 50° C. to 700° C., or a sub-atmospheric chemical vapor deposition (SACVD) method. However, other deposition methods may be implemented. In particular, layer 22 or 24 may be formed by liquid deposition, deposition by printing techniques for organic materials, such as spin coating, silk-screening, spray, or inkjet, or deposition of glass by centrifugation for inorganic materials.

The insulating walls 34A, 34B of trench 32 may be made of a dielectric material, for example, of silicon oxide (SiO₂), of silicon nitride (Siₓ N_{y}, where x is approximately equal to 3 and y is approximately equal to 4, for example, Si₃N₄), of silicon oxynitride (particularly of general formula SiₓON_{y}, for example, Si₂ON₂), of hafnium oxide (HfO₂), or of diamond. Preferably, insulating walls 34A, 34B are made of silicon oxide. Preferably, insulating walls 34A, 34B are made of silicon oxide obtained by thermal oxidation. Insulating walls 34A, 34B may be formed by a deposition method, particularly a method of chemical deposition type (CVD), particularly by plasma-enhanced chemical vapor deposition (PECVD), for example, at temperatures in the range from 50° C. to 700° C. Insulating walls 34A, 34B may be formed by thermal oxidation, particularly at temperatures in the range from 700° C. to 1,200° C., preferably from 1,000° C. to 1,100° C. Dry or wet thermal oxidation methods may be used. Preferably, insulating walls 34A, 34B are formed by thermal oxidation. According to another embodiment, insulating walls 34A, 34B are formed by the deposition of a SiO₂ layer followed by an anneal at high temperature (for example, between 700° C. and 1,000° C.) to densify the oxide. This advantageously enables to avoid the diffusion of dopants from substrate 6 and from core 20 into insulating walls 34A, 34B, which might decrease the breakdown voltage of insulating walls 34A, 34B.

According to an embodiment, a layer of the electrically-insulating material forming insulating layer 22, 24 has a breakdown voltage per thickness unit which is smaller than the breakdown voltage per thickness unit of a layer of the electrically-insulating material forming insulating walls 34A, 34B.

The core is made of a filling material. The filling material may correspond to the material forming substrate 6, particularly in polycrystalline form, or may be another material than that forming the substrate. Its first function is to ensure the mechanical coherence of the electronic circuit. More generally, the filling material may correspond to an electrically-insulating, semiconductor, or electrically-conductive material. Core 20 is preferably made of a semiconductor material, for example, of silicon, of germanium, of silicon carbide, of a III-V compound, such as GaN, InP, or GaAs, of a II-VI compound, for example ZnO, of tungsten (W), of copper (Cu), of glass based on oxides, particularly silicon oxide (SiO₂), sodium oxide (Na₂O), calcium oxide (CaO), or boron oxide (B₂O₃). Preferably, core 20 is made of polysilicon. Preferably, it is a material compatible with manufacturing methods implemented in microelectronics. Core 20 may correspond to a multilayer structure of different semiconductor materials. Core 20 may be heavily doped, lightly doped, or non-doped.

Dimensions L, Eₒₓ, P vary according to the targeted applications. According to an embodiment, the lateral dimension L of trench 32 varies from 0.1 μm to 10 μm, preferably from 2 μm to 4 μm. The thickness P of substrate 6 after thinning varies from 2 μm to 150 μm. The aspect ratio, P/L, may be in the range from 1 to 100, for example, equal to approximately 25. The thickness Eₒₓ of each insulating walls 34A, 34b may be in the range from 10 nm to 2 μm, preferably from 100 nm to 400 nm, for example, approximately 200 nm. The ratio of the thickness Eₒₓ of each insulating wall 34A, 34B to the lateral dimension L of each trench 32 is smaller than 0.5.

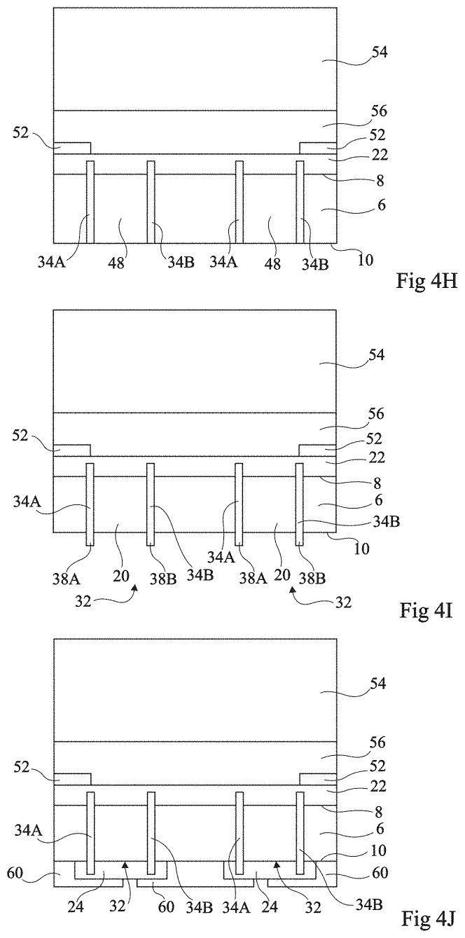

FIGS. 4A to 4J are partial simplified cross-section views of structures obtained at successive steps of an embodiment of a method of manufacturing the electric insulation trench 32 of the electronic circuit 30 of FIG. 3.

FIG. 4A shows the structure obtained after the forming of openings 40, two openings 40 being shown in FIG. 4A, extending in substrate 6 from surface 8 at the desired location of each trench 32, substrate 6 initially having a thickness greater than the previously-described thickness P. The depth and the width of each opening 40 are selected according to the desired dimensions of the trench and to the implemented methods. According to an embodiment, the depth of each opening 40 in substrate 6 is greater than the final thickness P of substrate 6. Opening 40 may be formed by photolithography steps, comprising the deposition of a resin layer on surface 8, the forming of an opening in the resin layer on the desired location of each opening 40, the etching of opening 40 in substrate 6 in line with each opening formed in the resin layer, and the removal of the resin layer. As an example, openings 40 may be formed by a dry etching. It is possible, if need be, to provide forming a hard mask before the lithography steps.

FIG. 4B shows the structure obtained after the forming of an insulating layer 42, for example, by a thermal oxidation step, on surface 8 and in each opening 40. The thermal oxidation method causes the transformation of a portion of substrate 6 into an oxide and thus a displacement of surface 8.

FIG. 4C shows the structure obtained after the deposition over the entire structure of a layer 44 of the filling material covering surface 8 and substantially totally filing each opening 40.

FIG. 4D shows the structure obtained after the removal of the materials located above surface 8 to only keep, in each opening 40, a portion 46 of insulating layer 42 and a portion 48 of layer 44 of the filling material. The removal step may comprise a step of chemical-mechanical polishing or CMP of insulating layer 42 and of the layer of filling material 44 all the way to surface 8. Each insulating portion 46 comprises insulating walls 34A, 34B and a bottom side 50 covering the bottom of opening 40.

FIG. 4E shows the structure obtained after a selective etching of substrate 6 and of the following portions 48 across portion of their thickness on the side of front surface 8 to expose the upper ends 36A, 36b of insulating portions 46. The etching is an etching selective over the material forming insulating portions 46. According to an embodiment, substrate 6 and filling portions 48 are etched simultaneously. The etching is for example a wet etching for example based on potassium hydroxide (KOH) and/or tetraethylammonium hydroxide (TMAH), a dry etching of plasma type or a gaseous etching for example based on xenon difluoride (XeF₂) or an etching of physical ion beam type. As a variation, it is possible not to etch filling portions 48 or to etch them down to a different depth than substrate 6.

FIG. 4F shows the structure obtained after the forming of the elements of the electronic circuit located on the side of front surface 8 of substrate 6. This may particularly comprise the forming of insulating layer 22 and of other elements 52, particularly electronic components or conductive pads, schematically shown by rectangles. Insulating layer 22 covers, for each trench, end portions 36A, 36B and is in contact therewith. Insulating layer 22 may be formed by a chemical vapor deposition method of PECVD or SACVD type. However, other CVD-type deposition methods may be implemented.

FIG. 4G shows the structure obtained after the gluing of a handle 54 to substrate 6 on the side of front surface 8, for example, via a glue layer 56. Handle 54 for example corresponds to a glass or silicon support. The thickness of handle 54 is for example in the range from 0.3 mm to 1 mm.

FIG. 4H shows the structure obtained after the thinning of substrate 6 on the side of rear surface 10 across a portion of the thickness of substrate 6 and the etching of bottom sides 50 to expose filling portions 48 and delimit insulating walls 34A, 34B. The removal step may comprise a chem.-mech. polishing step formed on the side of rear surface 10.

FIG. 4I shows the structure obtained after a selective etching, on the side of rear surface 10 of substrate 6, of substrate 6 and of filling portions 48 across a portion of their thickness to expose the end portions 38A, 38B of insulating walls 34A, 34B. The etching is an etching selective over the material forming insulating walls 34A, 34B. According to an embodiment, substrate 6 and filling portions 48 are etched simultaneously. The etching is for example a wet etching, for example based on potassium hydroxide (KOH) and/or tetraethylammonium hydroxide (TMAH), a dry etching of plasma type or a gaseous etching for example based on xenon difluoride (XeF₂) or an etching of physical ion beam type. Trenches 32, each comprising core 20, are then obtained. As a variation, it is possible for filling portions 48 not to be etched and then to directly form the cores of trenches 32.

FIG. 4J shows the structure obtained after the forming of the elements of the electronic circuit located on the side of rear surface 10 of substrate 6. This may in particular comprise the forming of insulating layers 24 for each trench 32 and of electrically-conductive contact pads 60. Insulating layer 24 may be formed by a chemical vapor deposition method of PECVD or SACVD type. However, other CVD-type deposition methods may be implemented. Methods of deposition of inorganic insulating materials may also be envisaged, and advantageously photosensitive materials commercialized by Shin-Etsu MicroSi under trade name SiNR™, for example.

The method may comprise a subsequent step of removal of handle 54.

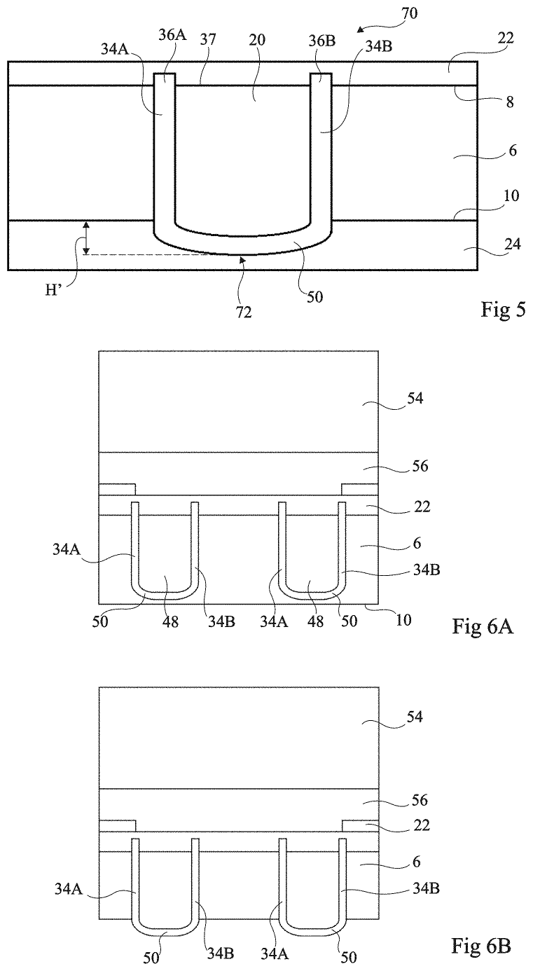

FIG. 5 shows an embodiment of an electronic circuit 70 comprising an electric insulation trench 72. Trench 72 comprises all the elements of the trench 32 shown in FIG. 3, with the difference that insulating walls 34A, 34B are continued at their lower end by a bottom side 50, which then extends outside of substrate 6, on the side of rear surface 10, in insulating layer 24, and which couples insulating walls 34A, 34b, core 20 being in contact with bottom side 50. Bottom side 50 is formed of the same material as insulating walls 34A, 34B.

The height H′ protruding from surface 10 of bottom side 50 in insulating layer 24 is in the range from 0.05 μm to 5 μm, for example, approximately 0.5 μm. In the embodiment shown in FIG. 5, the thickness of insulating layer 24, measured along the stacking direction of the layers on surface 8 or 10, is greater than height H′. As a variation, the thickness of insulating layer 24 may be substantially equal to height H′ or even smaller.

In the embodiment shown in FIG. 5, insulating walls 34A, 34B of trench 72 comprise end portions 36A, 36B, which protrude from substrate 6 on the side of front surface 8 and trench 72 comprises bottom side 50, which protrudes from substrate 6 on the side of rear surface 10 of substrate 6. According to the envisaged applications, insulating walls 34A, 34B of trench 72 may protrude from substrate 6 on the side of rear surface 10 and trench 72 may comprise a bottom side protruding from substrate 6 on the side of front surface 8, or trench 72 may comprise two bottom sides, one protruding from substrate 6 on the side of front surface 8 and the other one protruding from substrate 6 on the side of rear surface 10.

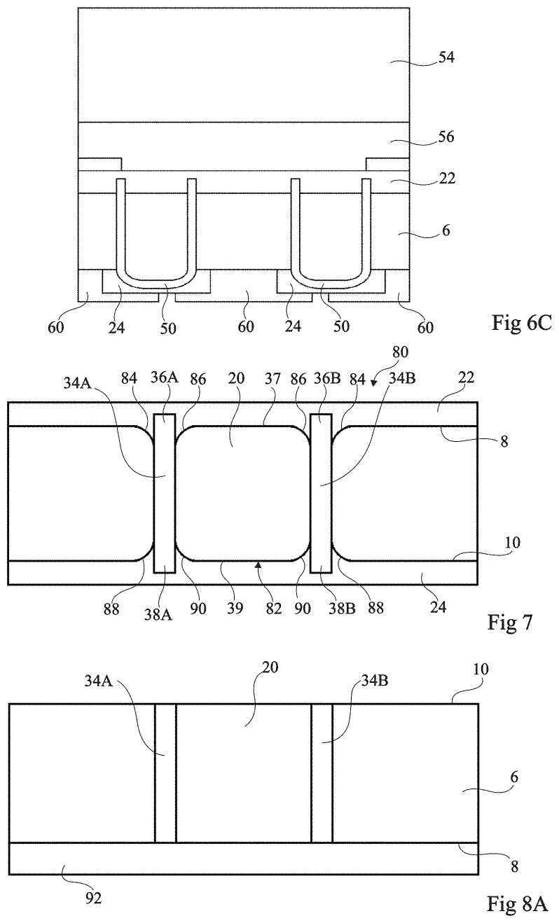

FIGS. 6A to 6C are partial simplified cross-section views of structures obtained at successive steps of an embodiment of a method of manufacturing the electric insulation trench 72 of the electronic circuit 70 of FIG. 5.

The initial steps of the method are the same as those which have been previously described in relation with FIGS. 4A to 4G.

FIG. 6A shows the structure obtained after the thinning of substrate 6 on the side of rear surface 10 across a portion of the thickness of substrate 6, with a stop of the etching before bottom sides 50 have been reached or with a stop on bottom sides 50. The removal step may comprise a step of chem.-mech. polishing of substrate 6 formed on the side of rear surface 10.

FIG. 6B shows the structure obtained after the etching of substrate 6 on the side of rear surface 10 across a portion of the thickness of substrate 6 with an etching which is selective over the material forming the bottom sides 50 and insulating walls 34A, 34B. The etching may be a wet etching for example based on potassium hydroxide (KOH) and/or tetraethylammonium hydroxide (TMAH), a dry etching of plasma type or a gaseous etching based on xenon difluoride (XeF₂), or an etching of physical ion beam type.

FIG. 6C shows the structure obtained after the forming of the elements of the electronic circuit located on the side of rear surface 10 of substrate 6. This may in particular comprise the forming of insulating layer 24 for each trench 32 and of electrically-conductive contact pads 60 as previously-described in relation with FIG. 4J.

The method may comprise a subsequent step of removal of handle 54.

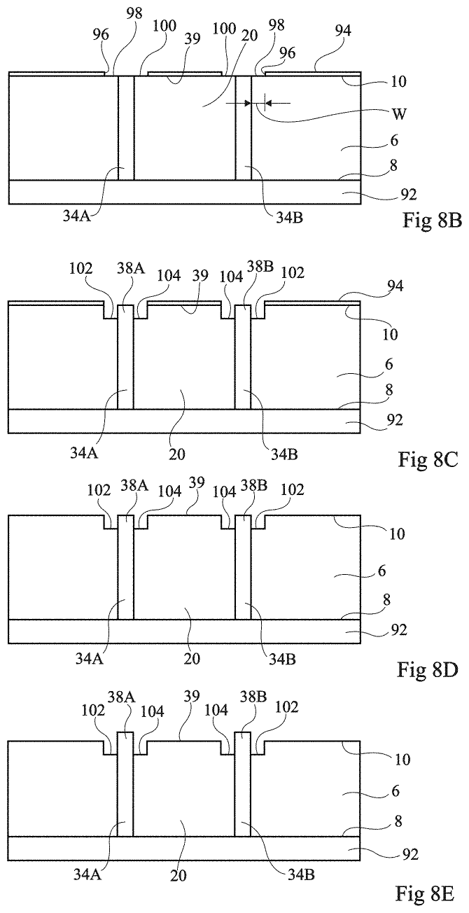

FIG. 7 shows an embodiment of an electronic circuit 80 comprising an electric insulation trench 82. Trench 82 comprises all the elements of the trench 32 shown in FIG. 3, with the difference that the junction between the front surface 8 of substrate 6 and each insulating wall 34A, 34B comprises an edge 84 rounded towards the inside of substrate 6, that the junction between the front surface 37 of core 20 and each insulating wall 34A, 34B comprises an edge 86 rounded towards the inside of core 20, that the junction between the rear surface 10 of substrate 6 and each insulating wall comprises an edge 88 rounded towards the inside of substrate 6, and that the junction between the rear surface 39 of core 20 and each insulating wall 34A, 34B comprises an edge 90 rounded towards the inside of core 20. This advantageously enables to decrease point effects adversely affecting the voltage behavior of trench 82 at the junction between substrate 6 and insulating walls 34A, 34B and at the junction between core 20 and insulating walls 34A, 34B.

According to an embodiment, in the plane of FIG. 7, the radius of curvature of each rounded edge 84, 86, 88, 90 is greater than 0.05 μm, preferably greater than 0.2 μm.

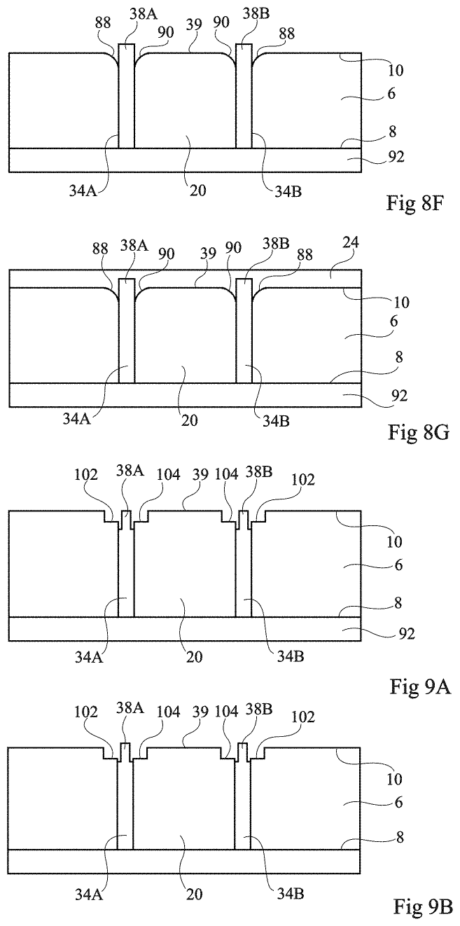

FIGS. 8A to 8G are partial simplified cross-section views of structures obtained at successive steps of an embodiment of a method of manufacturing the electric insulation trench of an electronic circuit similar to the electronic circuit 80 of FIG. 7.

FIG. 8A shows the structure obtained after the implementation of the steps previously described in relation with FIGS. 4A to 4H. In FIG. 8A, the structure covering the front surface 8 of substrate 6 is schematically shown as a layer 92.

FIG. 8B shows the structure obtained after the forming of a mask layer 94 on rear surface 10 and the etching of openings 96 in mask layer 94, each opening 96 exposing the rear end of insulating walls 34A, 34B, a strip 98 of the rear surface 10 of substrate 6 contiguous to insulating wall 34A, 34B and a strip 100 of the rear surface 39 of core 20 contiguous to insulating wall 34A, 34B. According to an embodiment, the width W of each strip is greater than at least twice lateral dimension L, for example, approximately 10 μm.

FIG. 8C shows the structure obtained after the etching, in openings 96 of mask 94, of substrate 6, and of core down to a depth capable of varying between 0.05 μm and 2 μm, for example, approximately 200 nm, to form a groove 102 in substrate 6 and a groove 104 in core 20 on either side of each insulating wall 34A, 34B. This step causes the exposure of the end portions 38A, 38B of insulating walls 34A, 34B. The etching may be an anisotropic etching, for example, by reactive ion etching implementing a plasma based on SF₆ or by a BOSCH-type method.

FIG. 8D shows the structure obtained after the removal of mask 94.

FIG. 8E shows the structure theoretically obtained after the etching of substrate 6 and of core 20 down to a depth capable of varying between 0.05 μm and 5 μm, for example, approximately 0.5 μm. According to an embodiment, substrate 6 and filling portions 20 are simultaneously etched. The etching is for example an isotropic etching of KOH or TMAH chemical etching or dry etching. Theoretically, grooves 102, 104 are displaced with the rest of the rear surface 10 of substrate 6 and of the rear surface 39 of core 20 during the etching.

FIG. 8F shows the structure effectively obtained after the etching of substrate 6 and of core 20. Grooves 102, 104 have been modified during the etching to become rounded edges 88, 90.

FIG. 8G shows the structure obtained after the forming of the elements of the electronic circuit located on the side of rear surface 10 of substrate 6. This may in particular comprise the forming of insulating layer 24 as previously described.

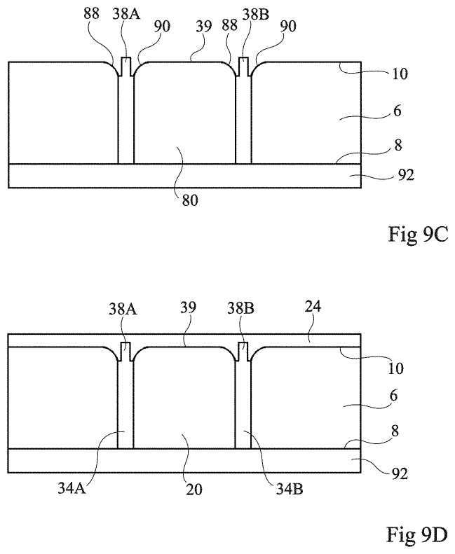

FIGS. 9A to 9D are partial simplified cross-section views of structures obtained at successive steps of another embodiment of a method of manufacturing the electric insulation trench of another electronic circuit similar to the electronic circuit 80 of FIG. 7.

The initial steps of the method are the same as those which have been previously described in relation with FIGS. 8A to 8D.

FIG. 9A shows the structure obtained after the etching of the exposed end portions 38A, 38B of insulating walls 34A, 34B, for example, down to a 50-nm depth. The etching is preferably an isotropic etching so that all the surfaces of the exposed ends of insulating walls 34A, 34B are etched.

FIGS. 9B, 9C, and 9D illustrate steps similar, respectively, to the steps previously described in relation with FIGS. 8E, 8F, and 8G.

This embodiment enables to more easily form rounded edges 90.

Specific embodiments have been described. Various alterations, modifications, and improvements will readily occur to those skilled in the art. In particular, although, in FIGS. 1 and 2, trenches 12 are shown as being perpendicular to trenches 14, it should be clear that the trenches may have a different direction. As an example, the portions 16 of substrate 6 may have, in top view, a hexagonal cross-section. Further, various embodiments with different variants have been described hereabove. It should be noted that various elements of these various embodiments and variants may be combined. In particular, the trench 72 shown in FIG. 5 may comprise rounded edges 84, 86 as shown in FIG. 7 at the level of end portions 36A, 36B and/or rounded edges 88 at the level of bottom side 50.

1. An electronic circuit comprising a semiconductor substrate having first and second opposite surfaces and electric insulation trenches extending in the substrate from the first surface to the second surface, each trench separating first and second portions of the substrate and comprising electrically-insulating walls made of a first electrically-insulating material and extending from the first surface to the second surface, and a core made of a filling material, separated from the substrate by the walls, wherein, for at least one of the trenches, the trench walls comprise electrically-insulating portions made of the first electrically-insulating material protruding from the first or second surface outside of the substrate and/or the trench comprises an electrically-insulating side made of the first electrically-insulating material protruding from the first or second surface outside of the substrate and coupling the trench walls.

2. The electronic circuit according to claim 1, further comprising an electrically-insulating layer of a second electrically-insulating material covering the electrically-insulating portions and/or the electrically-insulating side.

3. The electronic circuit according to claim 2, wherein the breakdown voltage of the first electrically-insulating material is greater than the breakdown voltage of the second electrically-insulating material.

4. The electronic circuit according to claim 1, wherein the height of the electrically-insulating portions or of the electrically-insulating side protruding from the first or second surface is in the range from 0.05 μm to 5 μm.

5. The electronic circuit according to claim 1, wherein, for at least one of the trenches, the junction between the first or second surface and each wall of the trench comprises an edge rounded towards the inside of the substrate.

6. The electronic circuit according to claim 5, wherein the radius of curvature of each rounded edge, in a plane perpendicular to the walls of the trench, is greater than 0.05 μm.

7. The electronic circuit according to claim 1, wherein the first electrically-insulating material is made of silicon oxide, of silicon nitride, of silicon oxynitride, of hafnium oxide, or of diamond.

8. The electronic circuit according to claim 7, wherein the walls are made of thermal silicon oxide.

9. The electronic circuit according to claim 1, wherein the filling material is different from the first electrically-insulating material.

10. The electronic circuit according to claim 9, wherein the filling material is selected from the group comprising silicon, germanium, silicon carbide, III-V compounds, and II-VI compounds.

11. The electronic device according to claim 1, wherein the substrate is preferably made of silicon, of germanium, of silicon carbide, of a III-V compound, or of a II-VI compound.

12. The electronic circuit according to claim 1, comprising, for at least one of the first portions and one of the second portions, at least first and second electronic components, the first electronic component resting on the first portion of the substrate and the second electronic component resting on the second portion of the substrate, one of the electric insulation trenches separating the first portion from the second portion.

13. A method of manufacturing the electronic circuit according to claim 1, comprising the successive steps of:
a) forming openings in substrate from the first surface across a portion of the substrate thickness;
b) forming an electrically-insulating layer of the first electrically-insulating material at least in each opening;
c) depositing a layer of the filling material in each opening in contact of the first electrically-insulating layer; and
d) thinning the substrate from the second surface to bring the second surface closer to the first surface to reach at least the electrically-insulating layer and form, for at least one of the trenches, the electrically-insulating portions of the first electrically-insulating material protruding from the first surface outside of the substrate and/or the electrically-insulating side of the first electrically-insulating material protruding from the second surface outside of the substrate and coupling the trench walls.

14. The method according to claim 13, wherein step b) comprises a thermal oxidation step.

15. The method according to claim 13, further comprising the steps of:
e) forming, for at least one of the trenches, a groove in the substrate along each wall of the trench, on the side of the first or second surface; and
f) etching the substrate across a portion of its thickness, whereby the junction between the first or second surface and each wall of the trench comprises an edge rounded towards the inside of the substrate (6).
